(19) United States
(12) Patent Application Publication
(10) Pub. No.: US 2026/0051339 A1
(43) Pub. Date: Feb. 19, 2026

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Jeong Hwan KIM, Icheon-si Gyeonggi-do (KR); Na Yeong YANG, Icheon-si Gyeonggi-do (KR); Jung Shik JANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 19/068,448

(22) Filed: Mar. 3, 2025

(30) Foreign Application Priority Data
Aug. 16, 2024 (KR) 10-2024-0109862

(51) Int. Cl. G11C 5/06; H10B 43/10; H10B 43/27; H10B 43/40

(52) U.S. Cl. CPC G11C 5/063; H10B 43/10; H10B 43/27; H10B 43/40

(57) ABSTRACT

Provided herein is a semiconductor memory device and a method of manufacturing the semiconductor memory device. The semiconductor memory device includes a gate stacked body, a first semiconductor layer over the gate stacked body, a source insulating structure between the first semiconductor layer and the gate stacked body, a contact source layer disposed between the source insulating structure and the gate stacked body, a channel structure penetrating the gate stacked body and contacting the contact source layer, a memory layer between the gate stacked body and the channel structure, and a source contact structure coupled to the contact source layer and extending to penetrate the source insulating structure and the first semiconductor layer.

### CROSS-REFERENCE TO RELATED APPLICATION

The present application claims priority under 35 U.S. C. §119(a) to Korean Patent Application No. 10-2024-0109862, filed on Aug. 16, 2024, in the Korean Intellectual Property Office, which application is incorporated herein by reference in its entirety.

### BACKGROUND

### 1. Technical Field

Various embodiments of the present disclosure generally relate to a semiconductor memory device and a semiconductor memory device of an electronic system, and more particularly to a semiconductor memory device including a three-dimensional (3D) memory cell array and a method of manufacturing the semiconductor memory device.

### 2. Related Art

A semiconductor memory device may be applied to a small electronic device as well as electronic systems in various fields such as automobiles, medical fields, or data centers. Thus, there is a growing demand for the semiconductor memory device.

The semiconductor memory device may include a memory cell array, and the memory cell array may include a plurality of memory cells for storing data. The semiconductor memory device is classified into a two-dimensional (2D) semiconductor memory device including a 2D memory cell array and a 3D semiconductor memory device including a 3D memory cell array.

The plurality of memory cells of the 3D memory cell array are arranged in three dimensions. Thus, compared to the 2D memory cell array including the plurality of memory cells arranged on a plane, the 3D memory cell array is advantageous in achieving the large capacity of the semiconductor memory device. The integration degree of the 3D semiconductor memory device can be improved by increasing the number of the memory cells stacked. As the number of the stacked memory cells increases, the structural stability of the semiconductor memory device may be compromised.

### SUMMARY

An embodiment of the present disclosure may provide for a semiconductor memory device. The device may include a gate stacked body including a cell array region and a contact region extending from the cell array region, a first semiconductor layer disposed over the gate stacked body, a source insulating structure provided between the first semiconductor layer and the gate stacked body, a source structure disposed between the source insulating structure and the gate stacked body and including a contact source layer over the cell array region of the gate stacked body, a channel structure penetrating the cell array region of the gate stacked body and the source structure, and contacting the contact source layer, a memory layer disposed between the gate stacked body and the channel structure, and a source contact structure coupled to the contact source layer and extending to penetrate the source insulating structure and the first semiconductor layer.

In an embodiment, the source contact structure may include a first contact portion penetrating the source structure and the source insulating structure, and a second contact portion penetrating the first semiconductor layer.

In an embodiment, a single layer includes the contact source layer and the source contact structure.

An embodiment of the present disclosure may provide for a method of manufacturing a semiconductor memory device. The method may include forming a source insulating structure over a top surface of a semiconductor layer, forming a sacrificial stacked body over the source insulating structure, forming a first vertical structure to penetrate the sacrificial stacked body and the source insulating structure, forming a cell pillar structure penetrating the sacrificial stacked body at a position spaced apart from the first vertical structure, the cell pillar structure including a channel structure that has a portion protruding in a vertical direction compared to the first vertical structure, and a memory layer extending along a sidewall of the channel structure, forming a gate stacked body that is disposed over the sacrificial stacked body and surrounds the protruding portion of the cell pillar structure, removing a portion of the semiconductor layer from a back surface of the semiconductor layer, which faces in a direction opposite to the top surface, forming an opening that penetrates a remaining portion of the semiconductor layer to expose the first vertical structure, removing the first vertical structure through the opening, and replacing a portion of the memory layer and the sacrificial stacked body with a contact source layer through the opening and a region where the first vertical structure is removed.

### BRIEF DESCRIPTION OF THE DRAWINGS

FIG. 1 is a block diagram illustrating a semiconductor memory device according to an embodiment of the present disclosure.

FIGS. 2A and 2B are plan views illustrating the semiconductor memory device according to an embodiment of the present disclosure.

FIGS. 3A, 3B, 3C, and 3D are sectional views illustrating the semiconductor memory device according to embodiments of the present disclosure.

FIG. 4 is a sectional view illustrating the semiconductor memory device according to an embodiment of the present disclosure.

FIGS. 5A and 5B are plan views illustrating a source contact structure according to an embodiment of the present disclosure.

FIG. 6 is a sectional view illustrating the source contact structure according to an embodiment of the present disclosure.

FIGS. 7A, 7B, 7C, 7D, 7E, 7F, and 7G are sectional views illustrating embodiments of the semiconductor memory device provided through processes that are performed prior to a bonding process.

FIGS. 8A, 8B, 8C, 8D, 8E, 8F, and 8G are sectional views illustrating embodiments of the semiconductor memory device provided through processes that are performed after the bonding process.

FIG. 9 is a sectional view illustrating an embodiment of a semiconductor memory device provided through a process of removing an intervening insulating layer.

FIG. 10 is a block diagram illustrating an electronic system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure are directed to a semiconductor memory device and a method of manufacturing the semiconductor memory device, which can improve structural stability.

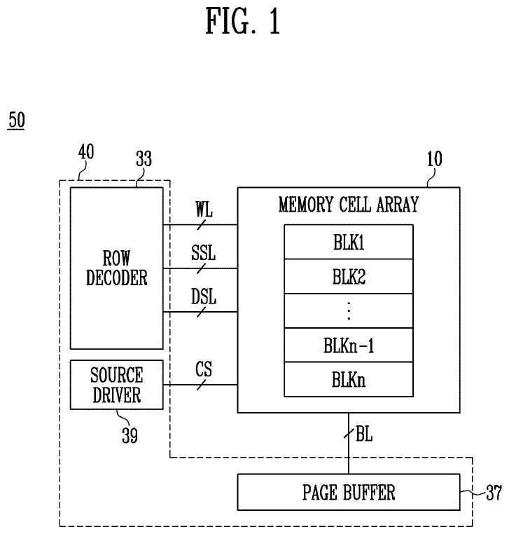

FIG. 1 is a block diagram illustrating a semiconductor memory device according to an embodiment of the present disclosure.

Referring to FIG. 1, the semiconductor memory device 50 includes a peripheral circuit 40 and a memory cell array 10.

The peripheral circuit 40 is configured to perform a program operation of storing data in the memory cell array 10, a read operation of outputting the data stored in the memory cell array 10, and an erase operation of erasing the data stored in the memory cell array 10. The peripheral circuit 40 includes a row decoder 33, a page buffer 37, and a source driver 39. Although not illustrated in the drawing, the peripheral circuit 40 may further include an input/output circuit, a control circuit, a voltage generation circuit, a column decoder, etc.

The memory cell array 10 includes a plurality of memory blocks BLK1 to BLKn (where n is a natural number greater than or equal to 2). The plurality of memory blocks BLK1 to BLKn are connected to the page buffer 37 through a plurality of bit lines BL. The plurality of memory blocks BLK1 to BLKn are connected to the row decoder 33 through a plurality of drain select lines DSL, a plurality of word lines WL, and a plurality of source select lines SSL. The plurality of memory blocks BLK1 to BLKn are connected to the source driver 39 through a plurality of common source lines CS.

Each memory block includes a plurality of memory cells. The plurality of memory cells are arranged in first to third directions that are different from each other, thus forming a 3D memory cell array. Each memory block may include at least one source select line SSL, at least one drain select line DSL, and a plurality of word lines WL. The plurality of word lines WL are stacked between at least one source select line SSL and at least one drain select line DSL. Some of the plurality of word lines WL may be used as dummy word lines. The plurality of common source lines CS may control a plurality of memory blocks. Each common source line CS may be connected to a corresponding memory block via a source structure.

The row decoder 33 may transmit operating voltages to the plurality of drain select lines DSL, the plurality of word lines WL, and the plurality of source select lines SSL. The page buffer 37 may control the plurality of bit lines BL or detect voltages or currents of the plurality of bit lines BL and then store the detected result. The source driver 39 may control a plurality of common source lines CS.

The memory cell array 10 may overlap the peripheral circuit 40. The plurality of bit lines BL, the plurality of word lines WL, the plurality of drain select lines DSL, the plurality of source select lines SSL, and a plurality of common source lines CS, which are connected to the memory cell array 10, are electrically connected to the peripheral circuit 40 via conductive structures.

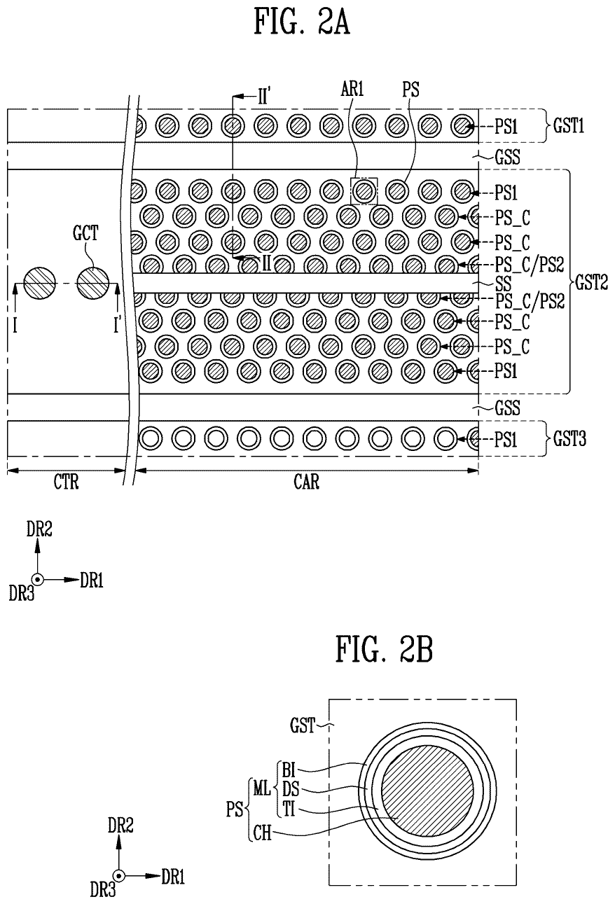

FIGS. 2A and 2B are plan views illustrating the semiconductor memory device according to an embodiment of the present disclosure.

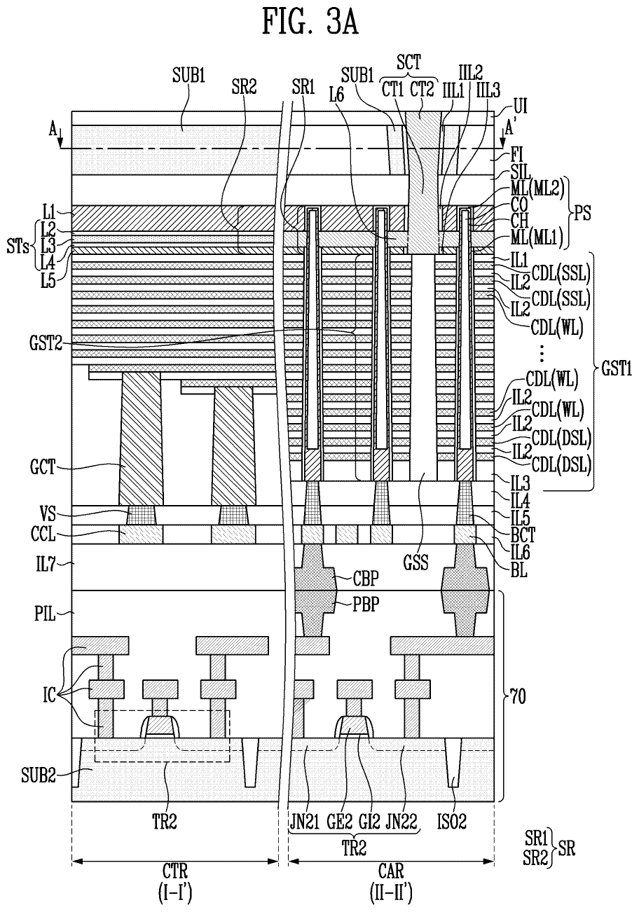

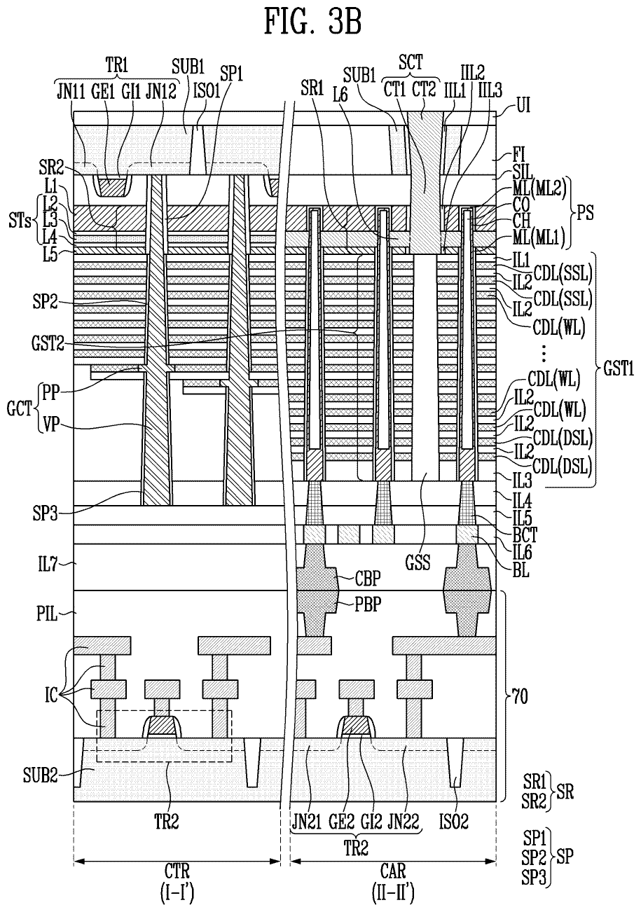

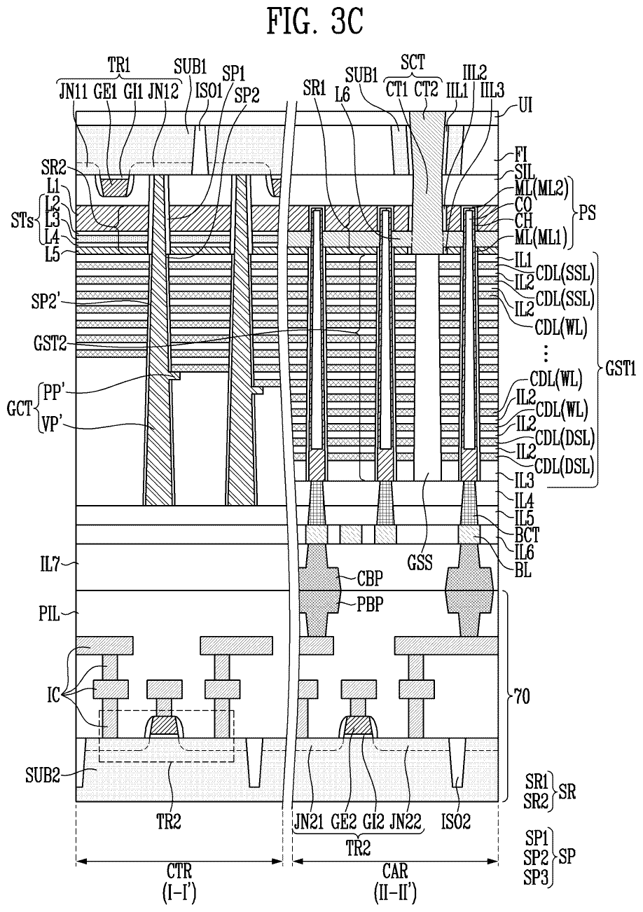

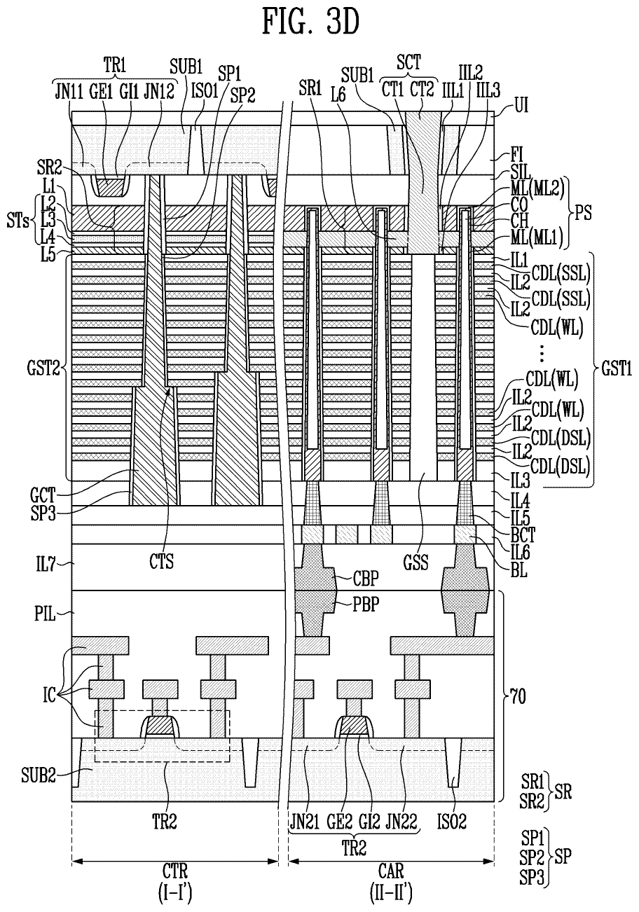

FIGS. 3A, 3B, 3C, and 3D are sectional views illustrating the semiconductor memory device according to embodiments of the present disclosure.

FIG. 2A illustrates the layout of a gate stacked body GST1, GST2 or GST3 of the semiconductor memory device. Each of FIGS. 3A, 3B, 3C, and 3D illustrates a cross-section of the semiconductor memory device taken along lines “I-I′”and “II-II′”illustrated in FIG. 2A.

Referring to FIGS. 2A, 3A, 3B, 3C, and 3D, the semiconductor memory device includes a gate stacked body GST1, GST2 or GST3, a plurality of cell pillar structures PS, a source structure SR, a source contact structure SCT, a source insulating structure SIL, a first semiconductor layer SUB1, a plurality of bit lines BL, a plurality of first conductive bonding patterns CBP, a plurality of conductive gate contact plugs GCT, and a bonding peripheral circuit structure 70.

The first semiconductor layer SUB1 is disposed over the gate stacked body GST1, GST2 or GST3. In an embodiment, the first semiconductor layer SUB1 may be used as a support substrate in the manufacturing process of the semiconductor memory device.

The first semiconductor layer SUB1 may include a semiconductor material. In an embodiment, the semiconductor material may include one or more of a group IV semiconductor, a group III-V compound semiconductor, and a group II-VI compound semiconductor. The group IV semiconductor may include monocrystalline silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The first semiconductor layer SUB1 may include a dielectric layer. The first semiconductor layer SUB1 may be a silicon-on-insulator (SOI) substrate, a germanium-on-insulator (GeOI) substrate, or a glass substrate.

The first semiconductor layer SUB1 may include an organic material. In an embodiment, the first semiconductor layer SUB1 may include graphene.

The first semiconductor layer SUB1 may be a bulk wafer or an epitaxial layer grown by a selective epitaxial growth (SEG) method.

The first semiconductor layer SUB1 may be a layer formed by a Metal Induced Lateral Crystallization (MILC) method, and may partially include metal.

The first semiconductor layer SUB1 may have a monocrystalline, polycrystalline, or amorphous state.

The first semiconductor layer SUB1 may include an impurity of group II, group III, group IV, group V, or group VI. In an embodiment, the first semiconductor layer SUB1 may include an n-well region doped with an n-type impurity and/or a p-well region doped with a p-type impurity.

The source insulating structure SIL is disposed between the first semiconductor layer SUB1 and the gate stacked body GST1, GST2, or GST3. The source structure SR is disposed between the source insulating structure SIL and the gate stacked body GST1, GST2, or GST3.

The gate stacked body GST1, GST2, or GST3 may include a cell array region CAR, and a contact region CTR extending from the cell array region CAR. The gate stacked body GST1, GST2, or GST3 includes a plurality of insulating layers IL1, IL2, and IL3 and a plurality of conductive layers CDL. Each of the plurality of insulating layers IL1, IL2, and IL3 and the plurality of conductive layers CDL includes surfaces extending in a first direction DR1 and a second direction DR2 that are different from each other. The plurality of insulating layers IL1, IL2, and IL3 and the plurality of conductive layers CDL may be alternately arranged in a third direction DR3 that is orthogonal to each surface. In an embodiment, the first direction DR1, the second direction DR2, and the third direction DR3 may be an X-axis direction, a Y-axis direction, and a Z-axis direction, respectively.

The gate stacked body GST1, GST2, or GST3 is partitioned by a gate separation structure GSS. In an embodiment, the plurality of gate stacked bodies may be arranged to extend in the first direction DR1 and be spaced apart from each other in the second direction DR2. The gate separation structure GSS may be disposed between gate stacked bodies that are adjacent to each other in the second direction DR2. For example, the semiconductor memory device includes the first gate stacked body GST1, the second gate stacked body GST2, and the third gate stacked body GST3 that are sequentially arranged in the second direction DR2. The gate separation structure GSS is disposed between the first gate stacked body GST1 and the second gate stacked body GST2, or disposed between the second gate stacked body GST2 and the third gate stacked body GST3.

The gate separation structure GSS may be formed of various materials. In an embodiment, the gate separation structure GSS may be formed of an insulating material without a conductive material and a semiconductor material. In an embodiment, the gate separation structure GSS may include an insulating layer covering a sidewall of the gate stacked body GST1, GST2, or GST3, and a core material disposed in a central region of the gate separation structure GSS. The core material may include one or both of the semiconductor material and the conductive material. The semiconductor material may one or both of an undoped semiconductor layer and a doped semiconductor layer. The doped semiconductor layer includes a conductive impurity. The conductive impurity includes an n-type impurity, a p-type impurity, or a mixture thereof. The conductive material may include metal, metal nitride, or the like.

The cell array region CAR of the gate stacked body GST1, GST2, or GST3 is penetrated by the plurality of cell pillar structures PS. The plurality of cell pillar structures PS may form a plurality of rows and a plurality of columns. Each row is composed of cell pillar structures PS arranged in a row in the first direction DR1, and each column is composed of cell pillar structures PS arranged in a row in the second direction DR2.

The plurality of cell pillar structures PS may include first pillar structures PS1 and center pillar structures PS_C. The first pillar structures PS1 are arranged adjacent to the edge of the gate stacked body GST1, GST2, or GST3. The edge of the gate stacked body GST1, GST2, or GST3 is formed along the gate separation structure GSS. The center pillar structures PS_C may be spaced further apart from the gate separation structure GSS than the first pillar structure PS1.

The gate stacked body GST1, GST2, or GST3 may include a select separation structure SS. The select separation structure SS may be formed shorter in the third direction DR3 compared to the gate separation structure GSS, and may be disposed inside the gate stacked body GST1, GST2, or GST3. The select separation structure SS and the gate separation structure GSS may extend in the first direction DR1. Some of the conductive layers CDL of each gate stacked body may be separated into source select lines SSL or drain select lines DSL by the select separation structure SS. The select separation structure SS may include an insulating material.

The center pillar structures PS_C may be arranged on both sides of the select separation structure SS. In an embodiment, the select separation structure SS may overlap some of the center pillar structures PS_C. In other words, the center pillar structures PS_C may include second pillar structures PS2 that overlap the select separation structure SS. The second pillar structures PS2 may be arranged along one side and the other side of the select separation structures SS that are adjacent to each other in the second direction DR2. The embodiments of the present disclosure are not limited thereto. Although not illustrated in the drawing, in an embodiment, the semiconductor memory device may further include dummy pillar structures overlapping the select separation structure SS, and the center pillar structures PS_C may be arranged on both sides of the dummy row composed of the dummy pillar structures so as not to overlap the select separation structure SS.

The insulating layers IL1, IL2, and IL3 of the gate stacked body GST1, GST2, or GST3 include a first insulating layer IL1, a plurality of second insulating layers IL2, and a third insulating layer IL3. The first insulating layer IL1 is disposed adjacent to the source structure SR, and the third insulating layer IL3 is spaced apart from the first insulating layer IL1 with a plurality of conductive layers CDL interposed therebetween. The plurality of second insulating layers IL2 may be arranged between the first insulating layer IL1 and the third insulating layer IL3, and may be alternately arranged one by one with the plurality of conductive layers CDL in the third direction DR3. Thus, the conductive layers CDL adjacent to each other in the third direction DR3 may be spaced apart from each other by the second insulating layer IL2 provided therebetween. The embodiment of the present disclosure is not limited thereto. In an embodiment, the conductive layers CDL that are adjacent to each other in the third direction DR3 may be spaced apart from each other by an air gap provided therebetween.

At least one of the conductive layers CDL of the gate stacked body GST1, GST2, or GST3 may be used as the source select line SSL (i.e., CDL(SSL)), at least one other may be used as the drain select line DSL (i.e., CDL(DSL)), and the remaining may be used as the plurality of word lines WL (i.e., CDL(WL)). Each of the plurality of conductive layers CDL may include various conductive materials such as a doped semiconductor layer, a metal layer, etc. The doped semiconductor layer may include a doped silicon layer. The metal layer may include tungsten, copper, molybdenum, etc. Each conductive layer CDL may further include a metal nitride layer. The metal nitride layer may include titanium nitride, tantalum nitride, molybdenum nitride, etc. The first insulating layer IL1, the plurality of second insulating layers IL2, and the third insulating layer IL3 may include an insulating material such as a silicon oxide layer (e.g., SiO₂), a silicon oxynitride layer (SiON), etc.

At least one of the source select line SSL and the drain select line DSL of the gate stacked body GST1, GST2, or GST3 may be partitioned narrower than each word line WL by the select separation structure SS. Each word line WL may be extended to overlap the select separation structure SS without being separated by the select separation structure SS.

FIG. 2B is an enlarged plan view of region “AR1” illustrated in FIG. 2A.

Referring to FIG. 2B, each cell pillar structure PS may include a channel structure CH and a memory layer ML. The channel structure CH extends in the third direction DR3 to penetrate the gate stacked body GST. The third direction DR3 is the longitudinal direction of the channel structure CH. The memory layer ML is interposed between the channel structure CH and the gate stacked body GST.

The memory layer ML includes a tunnel insulating layer TI, a data storage layer DS, and a blocking insulating layer BI. The tunnel insulating layer TI extends along the outer wall of the channel structure CH. The tunnel insulating layer TI may include an insulating material such as a silicon oxide layer. The data storage layer DS is interposed between the gate stacked body GST and the tunnel insulating layer TI. In an embodiment, the data storage layer DS may continuously extend along the outer wall of the tunnel insulating layer TI. In an embodiment, the data storage layer DS may be separated into a plurality of data storage patterns that are spaced apart from each other in the third direction DR3, and each data storage pattern is disposed between the conductive layer of the gate stacked body GST and the channel structure CH. The data storage layer DS may be formed of a material layer that may store changed data using Fowler-Nordheim tunneling. In an embodiment, the data storage layer DS may be formed of a charge trap insulating layer, a floating gate layer, or an insulating layer including conductive nanodots. The charge trap insulating layer may include a silicon nitride layer. The blocking insulating layer BI is interposed between the gate stacked body GST and the data storage layer DS. The blocking insulating layer BI may include at least one of a silicon dioxide layer (SiO₂) and a high-k dielectric layer having a higher dielectric constant than that of the silicon dioxide layer. The high-k dielectric layer may include an aluminum oxide layer, a hafnium oxide layer, or the like.

Referring to FIGS. 2A, 3A, 3B, 3C, and 3D, the arrangement of the plurality of memory cell strings of the memory cell array 10 described with reference to FIG. 1 follows the arrangement of the plurality of cell pillar structures PS, so the plurality of memory cell strings are arranged in the first direction DR1 and the second direction DR2. Each memory cell string includes a plurality of memory cells formed at the intersections of the channel structure CH and the plurality of word lines WL, a source select transistor formed at the intersection of the channel structure CH and the source select line SSL, and a drain select transistor formed at the intersection of the channel structure CH and the drain select line DSL. The source select transistor, the plurality of memory cells, and the drain select transistor are connected in series by the channel structure CH to form a memory cell string. Thus, each of the plurality of memory cell strings includes a plurality of memory cells arranged along the third direction DR3, and the plurality of memory cell strings are arranged in the first direction DR1 and the second direction DR2. Thereby, the semiconductor memory device may include a 3D memory cell array including memory cells arranged in three dimensions.

Each cell pillar structure PS may extend to penetrate the gate stacked body GST1, GST2, or GST3 and penetrate the source structure SR. The source structure SR may include a first source stacked body SR1 and a second source stacked body SR2. The first source stacked body SR1 is disposed between the cell array region CAR of the gate stacked body GST1, GST2, or GST3 and the source insulating structure SIL, and the second source stacked body SR2 is disposed between the contact region CTR of the gate stacked body GST1, GST2, or GST3 and the source insulating structure SIL.

The first source stacked body SR1 of the source structure SR includes a contact source layer L6. The contact source layer L6 is disposed over the cell array region CAR of the gate stacked body GST1, GST2, or GST3. The contact source layer L6 may penetrate the memory layer ML to contact the channel structure CH and surround a portion of the sidewall of the channel structure CH.

The channel structure CH may be formed of a semiconductor material that may be used as a channel region of the memory cell string, and the semiconductor material may include silicon (Si), germanium (Ge), or a mixture thereof. The channel structure CH may have various shapes. In an embodiment, the central region of the channel structure CH may be filled with a core insulating layer CO. Each end of the channel structure CH facing the bit line BL and the source structure SR contains a conductive impurity. The conductive impurity includes an n-type impurity, a p-type impurity, or a mixture thereof. In an embodiment, each end of the channel structure CH may be composed of an n-type doped region containing the n-type impurity as a majority carrier.

The first source stacked body SR1 of the source structure SR may be formed as a multilayer structure including the contact source layer L6. In an embodiment, the first source stacked body SR1 of the source structure SR may further include a first source layer L1 and a second source layer L5 in addition to the contact source layer L6. The first source layer L1 is disposed between the contact source layer L6 and the source insulating structure SIL. The first source layer L1 may be extended to surround the cell pillar structure PS and overlap the contact region CTR of the gate stacked body GST1, GST2, or GST3. The second source layer L5 is disposed between the contact source layer L6 and the gate stacked body GST1, GST2, or GST3. The second source layer L5 may be extended to surround the cell pillar structure PS and overlap the contact region CTR of the gate stacked body GST1, GST2, or GST3.

A portion of the first source layer L1 and a portion of the second source layer L5 overlapping the contact region CTR of the gate stacked body GST1, GST2, or GST3 may form the second source stacked body SR2 of the source structure SR. The second source stacked body SR2 may further include a sacrificial stacked body STs in addition to the first source layer L1 and the second source layer L5. The sacrificial stacked body STs is disposed over the contact region CTR of the gate stacked body GST1, GST2, or GST3, and is disposed between the first source layer L1 and the second source layer L5.

Each of the first source layer L1, the second source layer L5, and the contact source layer L6 may include a doped semiconductor layer such as doped silicon. Each of the first source layer L1, the second source layer L5, and the contact source layer L6 includes a conductive impurity, and the conductive impurity includes an n-type impurity, a p-type impurity, or a mixture thereof. In an embodiment, each of the first source layer L1, the second source layer L5, and the contact source layer L6 may include the n-type impurity as the majority carrier. In an embodiment, each of the contact source layer L6 and the second source layer L5 may include the n-type impurity as the majority carrier, and the first source layer L1 may include the p-type impurity as the majority carrier.

The sacrificial stacked body STs includes at least one layer interposed between the first source layer L1 and the second source layer L5. In an embodiment, the sacrificial stacked body STs may include a first passivation layer L2, a source sacrificial layer L3, and a second passivation layer L4. The first passivation layer L2 and the second passivation layer L4 may include a material different from that of each of the source sacrificial layer L3, the first source layer L1, and the second source layer L5. In an embodiment, the first passivation layer L2 and the second passivation layer L4 may include an oxide layer such as a silicon oxide layer, and the source sacrificial layer L3 may include one or both of a silicon layer and a silicon nitride layer.

The contact source layer L6 may penetrate the memory layer ML, and may separate the memory layer ML into a memory pattern ML1 and a dummy pattern ML2. The memory pattern ML1 is interposed between the gate stacked body GST1, GST2, or GST3 and the channel structure CH. The dummy pattern ML2 is interposed between the channel structure CH and the first source layer L1.

The source insulating structure SIL insulates the first semiconductor layer SUB1 from the source structure SR. A filling insulating layer FI may be disposed inside the first semiconductor layer SUB1. The filling insulating layer FI overlaps the plurality of cell pillar structures PS. The first semiconductor layer SUB1 and the filling insulating layer FI may be covered with an upper insulating layer UI.

The source contact structure SCT is coupled to the contact source layer L6. The source contact structure SCT extends to penetrate the source insulating structure SIL, the first semiconductor layer SUB1, and the upper insulating layer UI. The source contact structure SCT overlaps the gate separation structure GSS. The source contact structure SCT includes a first contact portion CT1 and a second contact portion CT2. The first contact portion CT1 penetrates the first source layer L1 and the second source layer L5. The first contact portion CT1 may be coupled to the gate separation structure GSS. The second contact portion CT2 extends from the first contact portion CT1 to penetrate the first semiconductor layer SUB1 and the upper insulating layer UI. The first contact portion CT1 and the second contact portion CT2 are disposed in the openings therefor, respectively. The opening for the first contact portion CT1 and the opening for the second contact portion CT2 are provided by etching processes performed in opposite directions. In this case, the first contact portion CT1 and the second contact portion CT2 may be formed to be tapered in opposite directions. For example, the first contact portion CT1 may be formed as a taper portion that becomes thinner as it moves away from the gate separation structure GSS, and the second contact portion CT2 may be formed as a reverse taper portion that becomes thinner as it approaches the gate separation structure GSS. In an embodiment the first contact portion CT1 and the second contact portion CT2 each have a taper portion. In an embodiment, the taper portion of the first contact portion CT1 is tapered in an opposite direction to the taper portion of the second contact portion CT2. In an embodiment, the taper portion of the first contact portion CT1 becomes thinner in a direction towards the second contact portion CT2. In an embodiment, the taper portion of the second contact portion CT2 becomes thinner in a direction towards the first contact portion CT1.

An intervening insulating layer IIL1, IIL2, or IIL3 is disposed between the first semiconductor layer SUB1 and the source contact structure SCT. The intervening insulating layer IIL1, IIL2, or IIL3 extends between the first source layer L1 and the source contact structure SCT, and extends between the second source layer L5 and the source contact structure SCT. The intervening insulating layer IIL1, IIL2, or IIL3 may protect the first semiconductor layer SUB1, the first source layer L1, and the second source layer L5 from the etching process of providing a space in which the contact source layer L6 is disposed.

The source contact structure SCT may be formed using a process of forming the contact source layer L6. In this case, a single layer may include the source contact structure SCT and the contact source layer L6 may. The single layer is a continuous material layer. In an embodiment, the source contact structure SCT and the contact source layer L6 may be formed as a single doped semiconductor layer. The conductive impurity of the single doped semiconductor layer includes the n-type impurity, the p-type impurity, or a mixture thereof. In an embodiment, the single doped semiconductor layer may include the n-type impurity as the majority carrier.

Although not illustrated in the drawing, the common source line CS described with reference to FIG. 1 may be disposed over the upper insulating layer UI, and the source contact structure SCT may be coupled to the common source line CS described with reference to FIG. 1.

The plurality of conductive gate contact plugs GCT overlap the contact region CTR of the gate stacked body GST1, GST2, or GST3. The plurality of conductive layers CDL of the gate stacked body GST1, GST2, or GST3 are coupled to the plurality of conductive gate contact plugs GCT, respectively. In the contact region CTR, the plurality of conductive layers CDL may be formed in various structures.

Referring to FIGS. 3A, 3B, and 3C, in an embodiment, the plurality of conductive layers CDL may form a stepped structure in the contact region CTR. Each of the plurality of conductive layers CDL includes a pad portion forming the steps of the stepped structure. The pad portion of the conductive layer CDL is coupled to a corresponding conductive gate contact plug GCT. The conductive gate contact plug GCT may extend from the pad portion of the conductive layer CDL to penetrate the fourth insulating layer IL4. The fourth insulating layer IL4 is interposed between the gate stacked body GST1 or GST2 and the bonding peripheral circuit structure 70, and extends to cover the stepped structure.

Referring to FIG. 3A, the conductive gate contact plug GCT does not penetrate the pad portion of the conductive layer, but contacts a surface of the pad portion facing the bonding peripheral circuit structure 70. In this case, at least one of the plurality of conductive layers CDL is interposed between the conductive gate contact plug GCT and the source insulating structure SIL.

Referring to FIGS. 3B and 3C, the conductive gate contact plug GCT may include a vertical portion VP or VP′ and a protruding portion PP or PP′. The vertical portion VP or VP′ extends to penetrate at least one of the plurality of conductive layers CDL in the contact region CTR and to penetrate the second source stacked body SR2. The protruding portion PP or PP′ protrudes laterally from the vertical portion VP or VP′ to contact the pad portion of a corresponding conductive layer CDL. A contact structure between the protruding portion PP or PP′ and the conductive layer CDL may vary.

Referring to FIG. 3B, the pad portion of the conductive layer CDL is penetrated by the vertical portion VP of a corresponding conductive gate contact plug GCT. The protruding portion PP of the conductive gate contact plug GCT surrounds the perimeter of the vertical portion VP at a level where the pad portion is disposed, and contacts the side of the pad portion. The sidewall of the conductive gate contact plug GCT is surrounded by an insulating spacer SP. The insulating spacer SP includes a first spacer SP1, a second spacer SP2, and a third spacer SP3. The first spacer SP1 is interposed between the second source stacked body SR2 and the vertical portion VP. Each of the second spacer SP2 and the third spacer SP3 is interposed between the gate stacked body (e.g., GST2) and the vertical portion VP. The second spacer SP2 and the third spacer SP3 may form an upper spacer and a lower spacer that are separated by the protruding portion PP. The second spacer SP2 may be coupled to the first spacer SP1.

Referring to FIG. 3C, the vertical portion VP′ of the conductive gate contact plug GCT is adjacent to the pad portion of a corresponding conductive layer CDL. The protruding portion PP′ of the conductive gate contact plug GCT extends from the vertical portion VP′ to overlap the upper surface of the pad portion facing the bonding peripheral circuit structure 70, and contacts the upper surface of the pad portion. The conductive gate contact plug GCT is surrounded by the insulating spacer SP. The insulating spacer SP includes the first spacer SP1 and the second spacer SP2′. The first spacer SP1 is interposed between the second source stacked body SR2 and the vertical portion VP′. The second spacer SP2′ extends along a portion of the sidewall of the vertical portion VP′ that protrudes toward the bonding peripheral circuit structure 70 compared to the first spacer SP1. The second spacer SP2′ is penetrated by the protruding portion PP′.

Referring to FIG. 3D, in an embodiment, the plurality of conductive layers CDL may be parallel to each other in the contact region CTR of the gate stacked body (e.g., GST2). The plurality of conductive gate contact plugs GCT penetrate the plurality of conductive layers CDL in the contact region CTR. The plurality of conductive gate contact plugs GCT extend to penetrate the fourth insulating layer IL4 and the second source stacked body SR2. The sidewall of the conductive gate contact plug GCT is surrounded by the insulating spacer SP.

The insulating spacer SP includes a first spacer SP1, a second spacer SP2, and a third spacer SP3. The first spacer SP1 is interposed between the second source stacked body SR2 of the source structure SR and the conductive gate contact plug GCT. Each of the second spacer SP2 and the third spacer SP3 is interposed between the gate stacked body GST2 and the conductive gate contact plug GCT. The second spacer SP2 and the third spacer SP3 may form an upper spacer and a lower spacer separated from each other by a contact surface CTS between the conductive gate contact plug GCT and a corresponding conductive layer CDL. The second spacer SP2 may be coupled to the first spacer SP1.

Referring to FIGS. 3A, 3B, 3C, and 3D, the first semiconductor layer SUB1 and the upper insulating layer UI may include an extended region overlapping the contact region CTR of the gate stacked body (e.g., GST2). The extended region of the first semiconductor layer SUB1 may be allocated for some components of the peripheral circuit 40 illustrated in FIG. 1. Thus, an embodiment of the present disclosure may reduce an area occupied by the peripheral circuit 40.

Referring to FIGS. 3B, 3C, and 3D, in an embodiment, the extended region of the first semiconductor layer SUB1 may be used as a region for pass transistors TR1 constituting the row decoder 33 of the peripheral circuit 40 illustrated in FIG. 1. An element isolation structure ISO1 is disposed in the extended region of the first semiconductor layer SUB1. The element isolation structure ISO1 is formed of an insulating material. The element isolation structure ISO1 partitions an active region of the first semiconductor layer SUB1, and penetrates the first semiconductor layer SUB1.

Each pass transistor TR1 is disposed between the first semiconductor layer SUB1 and the source insulating structure SIL. The pass transistor TR1 includes a gate insulating layer GI1, a gate electrode GE1, a first junction JN11, and a second junction JN12. The gate insulating layer GI1 and the gate electrode GE1 are stacked over the active region of the first semiconductor layer SUB1. The first junction JN11 and the second junction JN12 are disposed within the active region of the first semiconductor layer SUB1 on both sides of the gate electrode GE1, and are used as a source region and a drain region.

The conductive gate contact plug GCT penetrates the source insulating structure SIL to contact the first semiconductor layer SUB1. The conductive gate contact plug GCT may contact the second junction JN12, and may transmit an operating voltage to a corresponding conductive layer CDL under the control of the pass transistor TR1. The first spacer SP1 may extend to penetrate the source insulating structure SIL along the sidewall of the conductive gate contact plug GCT.

Referring to FIGS. 3A, 3B, 3C, and 3D, an insulating layer of a multilayer structure may be disposed between the fourth insulating layer IL4 and the bonding peripheral circuit structure 70. In an embodiment, a fifth insulating layer IL5, a sixth insulating layer IL6, and a seventh insulating layer IL7 are disposed between the fourth insulating layer IL4 and the bonding peripheral circuit structure 70.

The fifth insulating layer IL5 is interposed between the fourth insulating layer IL4 and the sixth insulating layer IL6. The fourth insulating layer IL4 and the fifth insulating layer IL5 are penetrated by a bit line contact plug BCT. The sixth insulating layer IL6 is interposed between the fifth insulating layer IL5 and the seventh insulating layer IL7. The sixth insulating layer IL6 is penetrated by the bit line BL. The bit line contact plug BCT electrically connects the channel structure CH and the bit line BL.

Referring to FIG. 3A, the fifth insulating layer IL5 is penetrated by a conductive via structure VS. The conductive via structure VS may be coupled to the conductive gate contact plug GCT. The sixth insulating layer IL6 may be penetrated by the conductive connecting line CCL. The conductive connecting line CCL may be coupled to the conductive via structure VS. Although not illustrated in the drawing, the conductive connecting line CCL may be coupled to the row decoder 33 of the peripheral circuit 40 described with reference to FIG. 1 via a separate conductive contact structure. Although not illustrated in the drawing, the row decoder 33 described with reference to FIG. 1 may be included in the bonding peripheral circuit structure 70 or may be provided over the first semiconductor layer SUB1.

Referring to FIGS. 3A, 3B, 3C, and 3D, the seventh insulating layer IL7 is interposed between the bonding peripheral circuit structure 70 and the sixth insulating layer IL6. The plurality of first conductive bonding patterns CBP are disposed in the seventh insulating layer IL7. In an embodiment, some of the plurality of first conductive bonding patterns CBP may be coupled to the bit line BL.

The bonding peripheral circuit structure 70 includes a second semiconductor layer SUB2, a plurality of interconnection structures IC, a plurality of transistors TR2, a plurality of second conductive bonding patterns PBP, and a peripheral circuit insulating structure PIL.

The source insulating structure SIL, the source structure SR, the gate stacked body GST1 or GST2, the conductive gate contact plug GCT, the bit line BL, and the first conductive bonding pattern CBP are disposed between the first semiconductor layer SUB1 and the second semiconductor layer SUB2. The second semiconductor layer SUB2 may be a bulk wafer or an epitaxial layer. The second semiconductor layer SUB2 may include a semiconductor material in a monocrystalline, polycrystalline, or amorphous state. The semiconductor material in the polycrystalline state may be a layer formed by an MICL method, and may partially contain metal. The semiconductor material may contain an impurity of group II, group III, group IV, group V, or group VI. In an embodiment, the semiconductor material of the second semiconductor layer SUB2 may include an n-well region doped with an n-type impurity and/or a p-well region doped with a p-type impurity. The second semiconductor layer SUB2 may further include a dielectric layer, an organic material, etc. In an embodiment, the second semiconductor layer SUB2 may include a monocrystalline silicon wafer or a monocrystalline silicon substrate.

Each transistor TR2 includes a gate insulating layer GI2, a gate electrode GE2, a first junction JN21, and a second junction JN22. The gate insulating layer GI2 and the gate electrode GE2 are stacked over the active region of the second semiconductor layer SUB2. The active region of the second semiconductor layer SUB2 is partitioned by the element isolation structure ISO2 disposed in the second semiconductor layer SUB2. The first junction JN21 and the second junction JN22 are disposed in the active region of the second semiconductor layer SUB2 on both sides of the gate electrode GE2, and are used as the source region and the drain region. The plurality of transistors TR2 form a portion of the peripheral circuit 40 illustrated in FIG. 1. In an embodiment, some of the plurality of transistors TR2 may form the page buffer 37 illustrated in FIG. 1.

A peripheral circuit insulating structure PIL may include two or more insulating layers interposed between the second semiconductor layer SUB2 and the seventh insulating layer IL7, and may cover the plurality of transistors TR2. The plurality of interconnection structures IC include lines and contact plugs disposed in the peripheral circuit insulating structure PIL. The plurality of interconnection structures IC may include a page buffer interconnection structure that is electrically connected to the page buffer 37 illustrated in FIG. 1. The page buffer interconnection structure may be coupled to the second junction JN22 of a corresponding transistor among the plurality of transistors TR2.

The plurality of second conductive bonding patterns PBP are disposed in the peripheral circuit insulating structure PIL on the interconnection structures IC. The plurality of second conductive bonding patterns PBP are bonded to the plurality of first conductive bonding patterns CBP. Each first conductive bonding pattern CBP and each second conductive bonding pattern PBP may include a bonding metal such as copper, aluminum, or tungsten.

In an embodiment, some of the plurality of second conductive bonding patterns PBP is coupled to the page buffer interconnection structure among the interconnection structures IC. The page buffer interconnection structure is coupled to a corresponding first conductive bonding pattern CBP by the second conductive bonding pattern PBP coupled thereto, and is electrically connected to the bit line BL via the first conductive bonding pattern CBP and the second conductive bonding pattern PBP.

The source contact structure SCT may have various cross-sections, such as circular, elliptical, semi-circular, semi-elliptical, and polygonal sections.

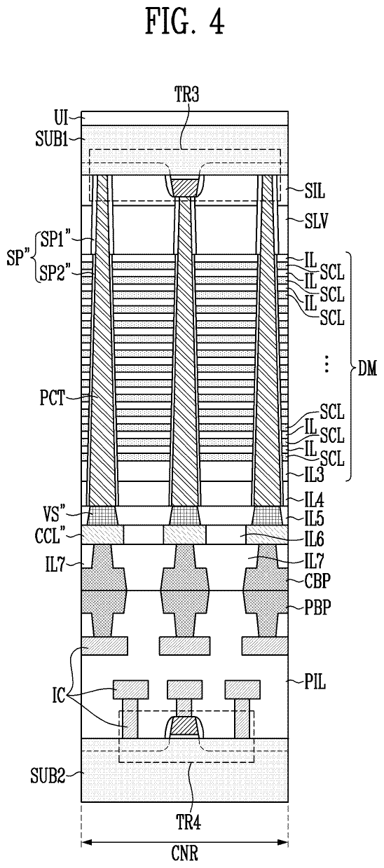

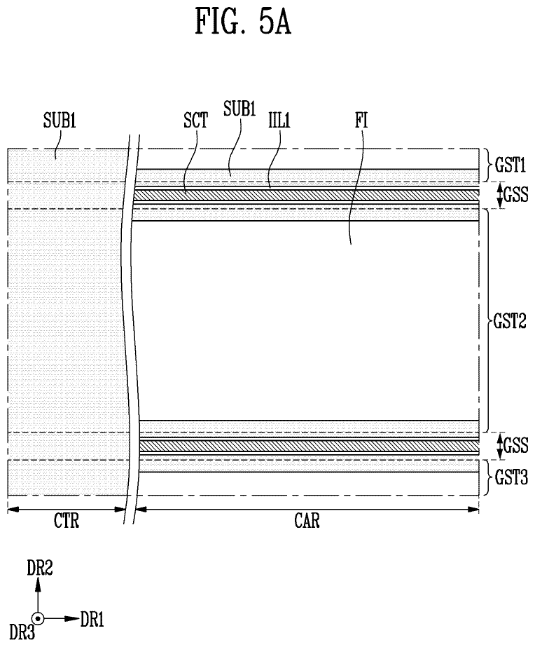

FIG. 4 is a sectional view illustrating the semiconductor memory device according to an embodiment of the present disclosure.

Referring to FIG. 4, each of the first semiconductor layer SUB1 and the second semiconductor layer SUB2 of the semiconductor memory device may include a coupling region CNR. The coupling region CNR of each of the first semiconductor layer SUB1 and the second semiconductor layer SUB2 does not overlap the gate stacked body GST1, GST2, or GST3 illustrated in FIG. 2A in the third direction DR3. The coupling region CNR of each of the first semiconductor layer SUB1 and the second semiconductor layer SUB2 may overlap the dummy stacked body DM in the third direction DR3. The dummy stacked body DM may be disposed at substantially the same level as the gate stacked body GST1, GST2, or GST3 illustrated in FIG. 2A. The gate stacked body GST1, GST2, or GST3 illustrated in FIG. 2A may extend to surround the perimeter of the dummy stacked body DM.

The dummy stacked body DM includes a plurality of insulating layers IL and a plurality of sacrificial layers SCL. The plurality of insulating layers IL may be disposed at substantially the same levels as the first, second, and third insulating layers IL1, IL2, and IL3 illustrated in FIGS. 3A, 3B, 3C, or 3D, and the plurality of sacrificial layers SCL may be disposed at substantially the same levels as the plurality of conductive layers CDL illustrated in FIGS. 3A, 3B, 3C, or 3D. The plurality of sacrificial layers SCL may include an insulating material having an etch selectivity with respect to the plurality of insulating layers IL.

The coupling region CNR of the first semiconductor layer SUB1 and the coupling region CNR of the second semiconductor layer SUB2 may be used as the region for the transistors TR3 and TR4. Each of the transistors TR3 and TR4 may be a configuration for an input/output circuit, a control circuit, a voltage generation circuit, or a column decoder of the semiconductor memory device.

The upper insulating layer UI, the source insulating structure SIL, the fourth, fifth, sixth, and seventh insulating layers IL4, IL5, IL6, and IL7, and the peripheral circuit insulating structure PIL illustrated in FIGS. 3A, 3B, 3C, or 3D extend to overlap the coupling region CNR of each of the first semiconductor layer SUB1 and the second semiconductor layer SUB2. A source level insulating layer SLV may be interposed between the source insulating structure SIL and the dummy stacked body DM. The source level insulating layer SLV may be disposed at substantially the same level as each of the first source stacked body SR1 and the second source stacked body SR2 of the source structure SR illustrated in FIGS. 3A, 3B, 3C, or 3D.

The transistor TR3 disposed over the first semiconductor layer SUB1 is coupled to a peripheral contact plug PCT. The peripheral contact plug PCT penetrates the source insulating structure SIL, the source level insulating layer SLV, the dummy stacked body DM, and the fourth insulating layer IL4. The peripheral contact plug PCT is formed of a conductive material for electrical connection. The sidewall of the peripheral contact plug PCT is surrounded by an insulating spacer SP″.

The insulating spacer SP″ includes a first spacer SP1″ and a second spacer SP2″. The first spacer SP1″ is interposed between the source level insulating layer SLV and the peripheral contact plug PCT. The second spacer SP2″ is interposed between the dummy stacked body DM and the peripheral contact plug PCT.

The peripheral contact plug PCT may be electrically connected to a corresponding first conductive bonding pattern CBP, a corresponding second conductive bonding pattern PBP, and a corresponding interconnection structure IC via a conductive via structure VS″ and a conductive connecting line CCL″. The conductive via structure VS″ is disposed inside the fifth insulating layer IL5. The conductive connecting line CCL″is disposed inside the sixth insulating layer IL6.

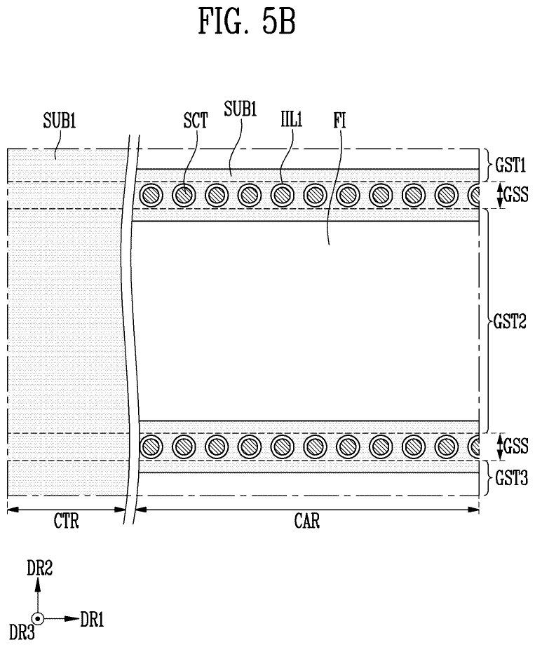

FIGS. 5A and 5B are plan views illustrating a source contact structure according to an embodiment of the present disclosure.

FIGS. 5A and 5B illustrate the layout of the first semiconductor layer SUB1 and the source contact structure SCT taken along the line “A-A′” illustrated in FIG. 3A.

Referring to FIGS. 5A and 5B, the first semiconductor layer SUB1 overlaps the contact region CTR and the cell array region CAR of the gate stacked body GST1, GST2, or GST3. A portion of the first semiconductor layer SUB1 corresponding to the cell array region CAR is penetrated by the filling insulating layer FI, and is disposed around the sidewall of the source contact structure SCT.

Referring to FIG. 5A, in an embodiment, the source contact structure SCT may overlap the gate separation structure GSS, and may extend in the first direction DR1 to be parallel to the gate separation structure GSS.

Referring to FIG. 5B, in an embodiment, the plurality of source contact structures SCT may overlap the gate separation structure GSS, and may be arranged to be spaced apart from each other in the first direction DR1. The first semiconductor layer SUB1 may surround the sidewall of each source contact structure SCT.

Referring to FIGS. 5A and 5B, an intervening insulating layer IIL1 may be disposed between the source contact structure SCT and the first semiconductor layer SUB1. The embodiments of the present disclosure is not limited thereto.

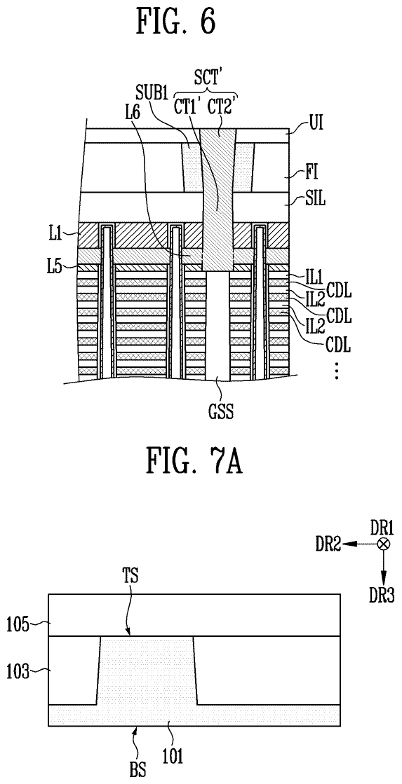

FIG. 6 is a sectional view illustrating the source contact structure according to an embodiment of the present disclosure.

Referring to FIG. 6, the source contact structure SCT′ overlaps the gate separation structure GSS, and is coupled to the contact source layer L6. The gate separation structure GSS partitions the plurality of conductive layers CDL and the plurality of insulating layers IL1 and IL2 into a gate stacked body.

The source contact structure SCT′ penetrates the first source layer L1, the second source layer L5, the source insulating structure SIL, and the upper insulating layer UI. The first semiconductor layer SUB1 is penetrated by the filling insulating layer FI, and is disposed around the source contact structure SCT′.

The first contact portion CT1′ of the source contact structure SCT′ directly contacts each of the first source layer L1 and the second source layer L5 without the intervention of the intervening insulating layer. The second contact portion CT2′ of the source contact structure SCT′ directly contacts the first semiconductor layer SUB1 without the intervention of the intervening insulating layer. In an embodiment, as the source contact structure SCT′ directly contacts the first semiconductor layer SUB1, current may flow more smoothly through the source contact structure SCT′ compared to when the intervening insulating layer is involved. In an embodiment, when the first semiconductor layer SUB1 directly contacting the source contact structure SCT′ is composed of a monocrystalline semiconductor layer, the flow of current may be improved compared to when the first semiconductor layer is a polycrystalline semiconductor layer.

Hereinafter, a manufacturing method for providing a semiconductor memory device according to an embodiment of the present disclosure will be described, focusing on a cell array region of the semiconductor memory device.

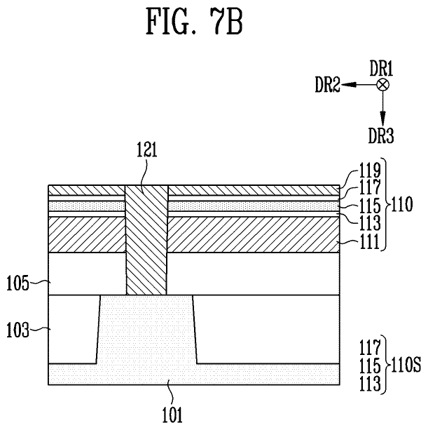

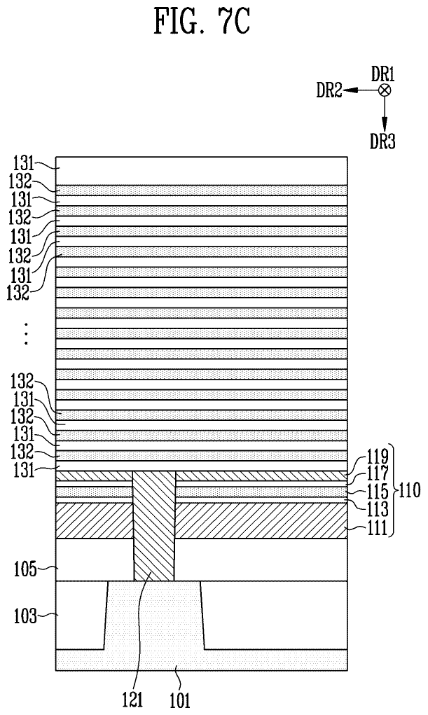

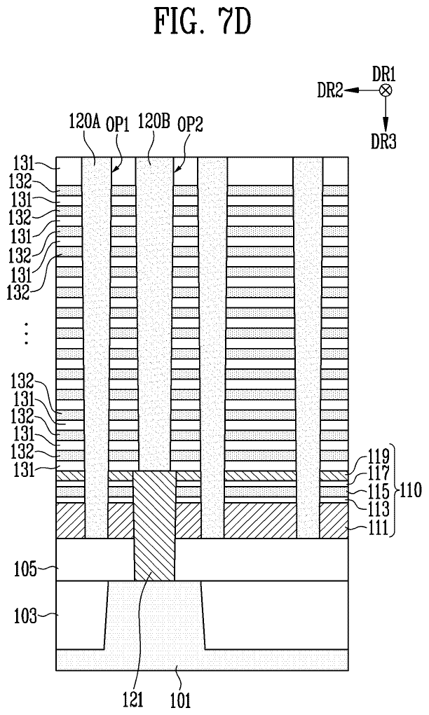

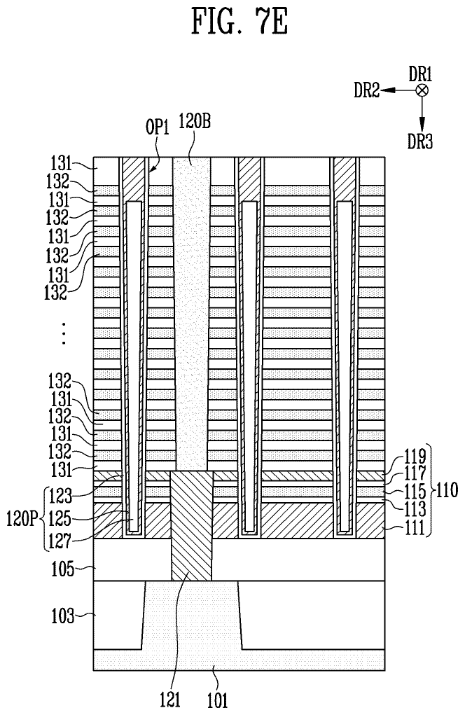

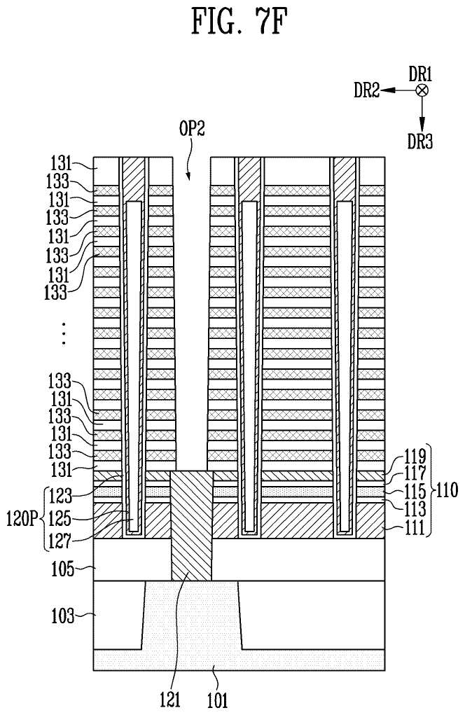

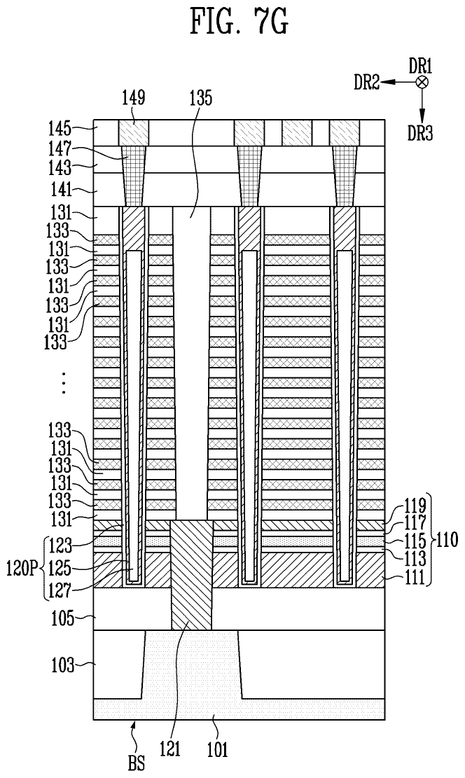

FIGS. 7A, 7B, 7C, 7D, 7E, 7F, and 7G are sectional views illustrating the semiconductor memory device provided through processes that are performed prior to a bonding process.

Referring to FIG. 7A, the filling insulating layer 103 is formed in the first semiconductor layer 101. The first semiconductor layer 101 may serve as a support substrate. The first semiconductor layer 101 may include a semiconductor material, and may be configured in various ways, like the first semiconductor layer SUB1 described with reference to FIGS. 3A, 3B, 3C, and 3D.

The filling insulating layer 103 extends in the first direction DR1 and the second direction DR2 in the cell array region. The filling insulating layer 103 is formed to a depth that penetrates a top surface TS of the first semiconductor layer 101 and does not penetrate a back surface BS of the first semiconductor layer 101 facing in the third direction DR3 opposite to the top surface TS of the first semiconductor layer 101.

Subsequently, the source insulating structure 105 is formed over the top surface TS of the first semiconductor layer 101. The source insulating structure 105 extends to cover the filling insulating layer 103. Although not illustrated in the drawing, before forming the source insulating structure 105, a process of forming the pass transistor TR1 illustrated in FIG. 4 may be performed.

Referring to FIG. 7B, a preliminary source structure 110 including a sacrificial stacked body 110S is formed over the source insulating structure 105. The sacrificial stacked body 110S may include a first passivation layer 113, a source sacrificial layer 115, and a second passivation layer 117 as in the sacrificial stacked body STs described with reference to FIGS. 3A, 3B, 3C, or 3D.

The preliminary source structure 110 may include a first source layer 111 and a second source layer 119 in addition to the sacrificial stacked body 110S. Each of the first source layer 111 and the second source layer 119 may be formed of a doped semiconductor layer containing a conductive impurity. The conductive impurity includes an n-type impurity, a p-type impurity, or a mixture thereof. The first source layer 111 may be formed over the source insulating structure 105 before forming the sacrificial stacked body 110S. The second source layer 119 may be formed over the sacrificial stacked body 110S after forming the sacrificial stacked body 110S.

Subsequently, a first vertical structure 121 is formed to penetrate the first source layer 111 of the preliminary source structure 110, the sacrificial stacked body 110S, and the second source layer 119. The first vertical structure 121 extends to penetrate the source insulating structure 105. The first vertical structure 121 is disposed so as not to overlap the filling insulating layer 103. The first vertical structure 121 is formed of a material different from that of the preliminary source structure 110 and the source insulating structure 105 to have an etch selectivity with respect to the preliminary source structure 110 and the source insulating structure 105. In an embodiment, the first vertical structure 121 may contain tungsten.

The first vertical structure 121 may be formed in the opening using the etching process that is performed from the top surface of the preliminary source structure 110 toward the first semiconductor layer 101. At this time, due to the characteristics of the etching process, the opening may be formed in a tapered shape that becomes thinner as it approaches the first semiconductor layer 101, and the first vertical structure 121 may have a structure corresponding to the tapered shape.

Referring FIG. 7C, the plurality of insulating layers 131 and the plurality of sacrificial layers 132 are alternately stacked one by one over the preliminary source structure 110. The plurality of sacrificial layers 132 are formed of a material different from that of the plurality of insulating layers 131 to have an etch selectivity with respect to the plurality of insulating layers 131. In an embodiment, the plurality of insulating layers 131 may include a silicon oxide layer, and the plurality of sacrificial layers 132 may include a silicon nitride layer.

The plurality of insulating layers 131 may include the first insulating layer, the plurality of second insulating layers, and the third insulating layer described with reference to FIGS. 3A, 3B, 3C, or 3D. The plurality of insulating layers 131 and the plurality of sacrificial layers 132 overlap the first vertical structure 121.

Referring to FIG. 7D, a first opening OP1 is formed to penetrate the plurality of insulating layers 131, the plurality of sacrificial layers 132, and the preliminary source structure 110. A second opening OP2 may be formed using an etching process of forming the first opening OP1. In an embodiment, while the first opening OP1 is formed, the second opening OP2 may be formed.

The first opening OP1 overlaps the filling insulating layer 103. The second opening OP2 overlaps the first vertical structure 121. The second opening OP2 penetrates the plurality of insulating layers 131 and the plurality of sacrificial layers 132 to expose the first vertical structure 121. The first vertical structure 121 may be used as an etching stop layer during the etching process of forming the second opening OP2.

Subsequently, the first opening OP1 and the second opening OP2 are filled with a sacrificial material. Thus, a second vertical structure 120A is formed in the first opening OP1 and a third vertical structure 120B is formed in the second opening OP2. The third vertical structure 120B is coupled to the first vertical structure 121. The sacrificial material for the second vertical structure 120A and the third vertical structure 120B are formed of a different material to have an etch selectivity with respect to the first vertical structure 121, the plurality of insulating layers 131, and the plurality of sacrificial layers 132. In an embodiment, the sacrificial material may contain amorphous carbon.

Referring to FIG. 7E, by removing the second vertical structure 120A illustrated in FIG. 7D, the first opening OP1 is exposed. Thereafter, a cell pillar structure 120P is formed in the first opening OP1. At this time, the third vertical structure 120B may be protected with a mask layer (not illustrated), and the mask layer may be removed after the cell pillar structure 120P is formed. The cell pillar structure 120P penetrates the preliminary source structure 110 at a position spaced apart from the first vertical structure 121, and has a portion that protrudes in a vertical direction compared to the first vertical structure 121 and extends into the plurality of insulating layers 131 and the plurality of sacrificial layers 132.

A step of forming the cell pillar structure 120P includes a step of forming the memory layer 123 along the surface of the first opening OP1 and a step of forming the channel structure 125 in the first opening OP1. The memory layer 123 may include the tunnel insulating layer TI, the data storage layer DS, and the blocking insulating layer BI illustrated in FIG. 2B. The step of forming the channel structure 125 may include a step of forming a liner semiconductor layer along the surface of the memory layer 123, and a step of filling the central region of the first opening OP1 with a core insulating layer 127 and a capping semiconductor layer. The capping semiconductor layer may be disposed over the core insulating layer 127, and may be formed as a doped semiconductor layer containing a conductive impurity. The conductive impurity includes an n-type impurity, a p-type impurity, or a mixture thereof. According to an embodiment, the capping semiconductor layer may include the n-type impurity as the majority carrier. The channel structure 125 may include a liner semiconductor layer and a capping semiconductor layer.

Referring to FIG. 7F, the third vertical structure 120B illustrated in FIG. 7E is removed. Thus, the second opening OP2 is exposed. Thereafter, the plurality of sacrificial layers 132 illustrated in FIG. 7E are replaced with the plurality of conductive layers 133 through the second opening OP2. Thus, a gate stacked body including the plurality of insulating layers 131 and the plurality of conductive layers 133 and partitioned by the second opening OP2 may be formed. The plurality of insulating layers 131 and the plurality of conductive layers 133 surround the protruding portion of the cell pillar structure 120P in the vertical direction compared to the preliminary source structure 110.

Although not illustrated in the drawing, after forming the plurality of conductive layers 133, a select separation structure may be formed so that at least one conductive layer from an uppermost layer is separated into the drain select lines.

Referring to FIG. 7G, the second opening OP2 illustrated in FIG. 7F may be filled with the gate separation structure 135. Subsequently, at least one insulating layer may be formed to cover the gate separation structure 135, the cell pillar structure 120P, the plurality of insulating layers 131, and the plurality of conductive layers 133. In an embodiment, a fourth insulating layer 141 and a fifth insulating layer 143 are sequentially stacked. Although not illustrated in the drawing, before forming the fifth insulating layer 143, the conductive gate contact plug described with reference to FIGS. 3A, 3B, 3C, or 3D may be formed.

Thereafter, a bit line contact plug 147 penetrating the fourth insulating layer 141 and the fifth insulating layer 143 may be formed. The bit line contact plug 147 is electrically connected to the channel structure 125 of the cell pillar structure 120P.

Subsequently, a sixth insulating layer 145 is formed on the fifth insulating layer 143, and a bit line 149 penetrating the sixth insulating layer 145 is formed. The bit line 149 is coupled to the bit line contact plug 147.

Although not illustrated in the drawing, after forming the bit line 149, an additional process of forming the first conductive bonding pattern may be performed. Further, the bonding peripheral circuit structure 70 illustrated in FIGS. 3A, 3B, 3C, or 3D may be manufactured and provided through a separate process, and then the first semiconductor layer and the second semiconductor layer of the peripheral circuit structure may be aligned so that the first conductive bonding pattern and the second conductive bonding pattern face each other. Subsequently, by bonding the first conductive bonding pattern and the second conductive bonding pattern of the peripheral circuit structure through a bonding process, the first conductive bonding pattern and the second conductive bonding pattern may be bonded to each other.

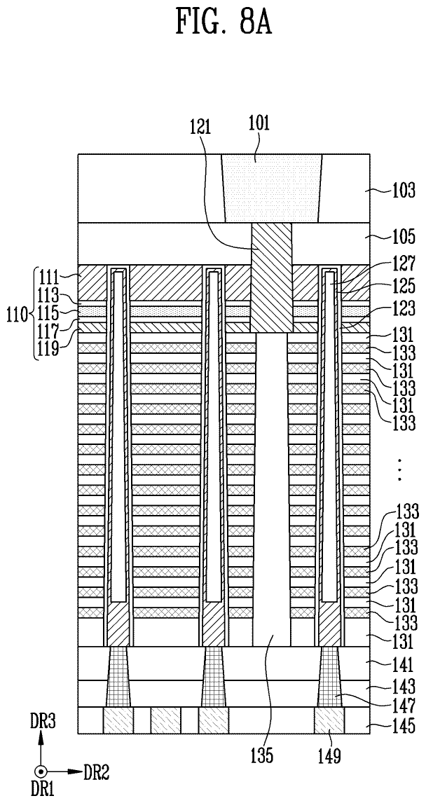

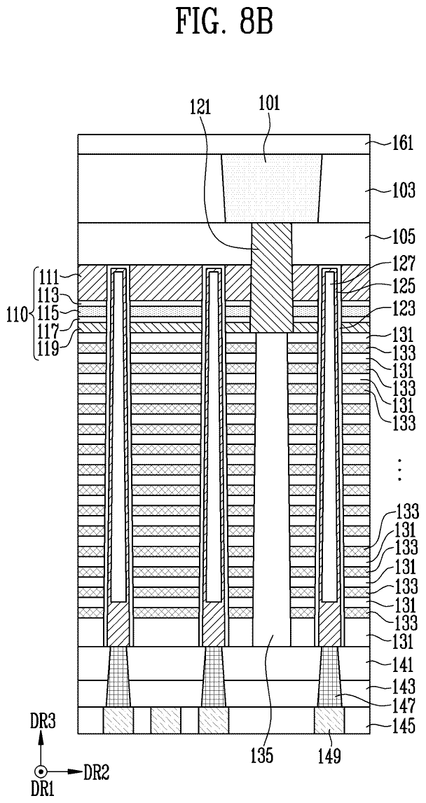

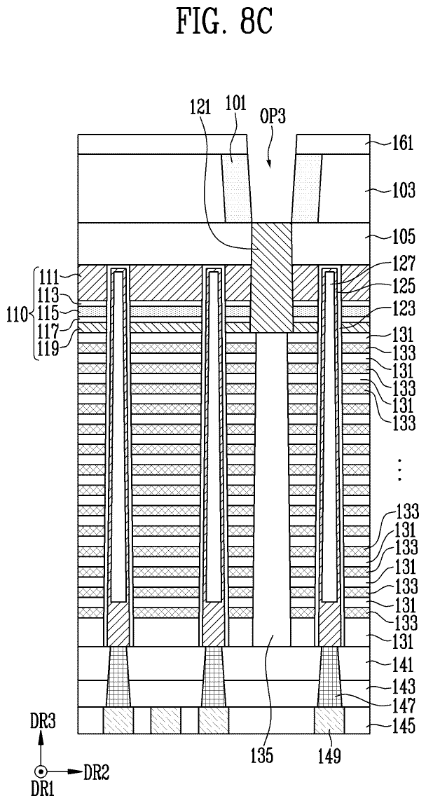

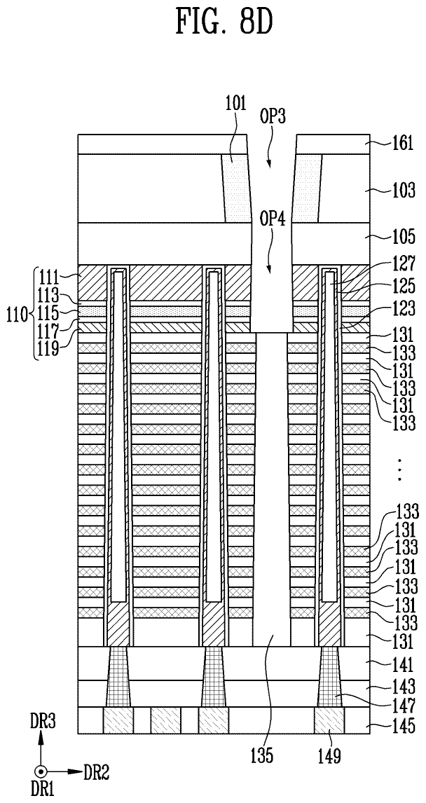

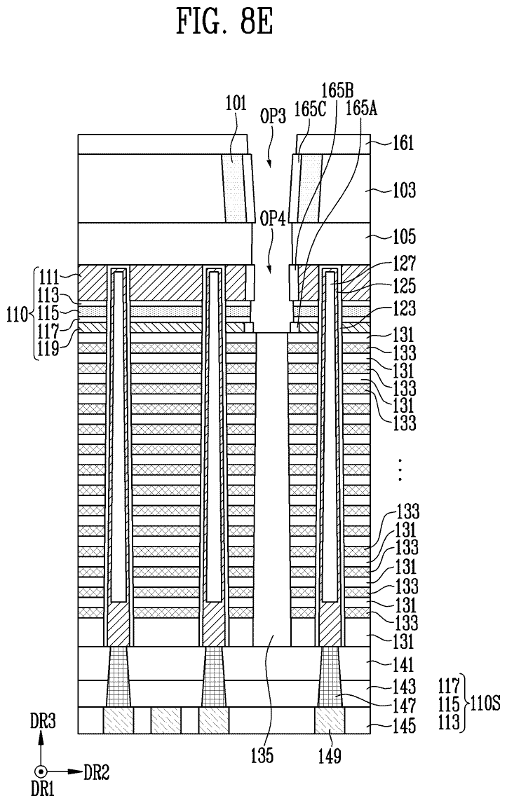

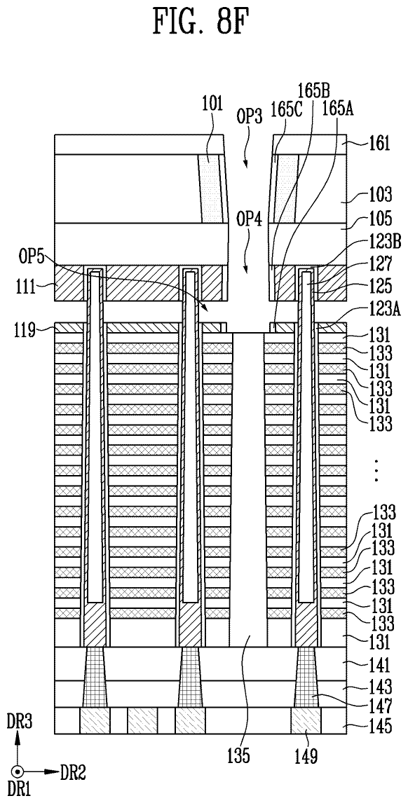

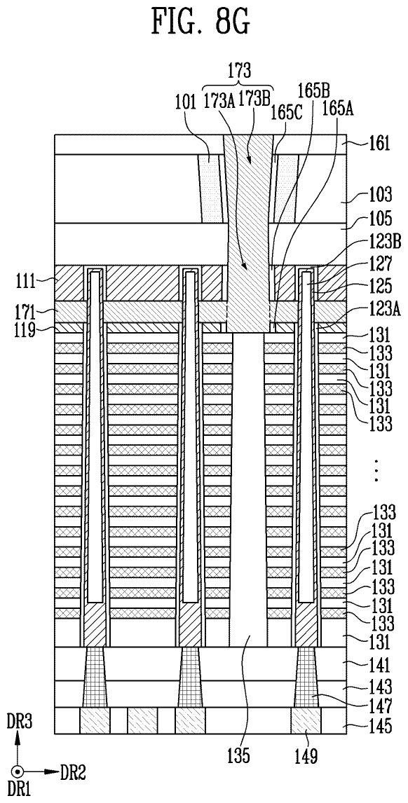

FIGS. 8A, 8B, 8C, 8D, 8E, 8F, and 8G are sectional views illustrating the semiconductor memory device provided through processes that are performed after the bonding process.

Referring to FIG. 8A, after the bonding process, a portion of the first semiconductor layer 101 is removed from the back surface BS of the first semiconductor layer 101 illustrated in FIG. 7G using a process such as a chemical mechanical polishing (CMP) process. At this time, since the filling insulating layer 103 may serve as the etching stop layer, the process of removing a portion of the first semiconductor layer 101 may be stopped when the filling insulating layer 103 is exposed.

The residual thickness of the first semiconductor layer 101 may be designed in various ways by controlling the formation depth of the filling insulating layer 103. In the embodiment of the present disclosure, by not completely removing the first semiconductor layer 101 but by leaving a portion thereof, it is possible to alleviate warpage stress caused by completely removing the first semiconductor layer 101.

Referring to FIG. 8B, an upper insulating layer 161 is formed to cover the first semiconductor layer 101 and the exposed filling insulating layer 103.

Referring to FIG. 8C, a third opening OP3 is formed to penetrate a portion of the upper insulating layer 161 overlapping the first vertical structure 121 and a portion of the first semiconductor layer 101. Thus, the first vertical structure 121 is exposed. The etching process for forming the third opening OP3 may be performed from the surface of the upper insulating layer 161 toward the gate separation structure 135. Due to the characteristics of the etching process, the third opening OP3 may be formed in a reverse taper shape that becomes thinner as it approaches the gate separation structure 135 and is opposite to the shape of the first vertical structure 121.

Referring to FIG. 8D, the first vertical structure 121 illustrated in FIG. 8C is removed through the third opening OP3. A region where the first vertical structure 121 is removed is defined as a fourth opening OP4. The shape of the fourth opening OP4 corresponds to that of the first vertical structure 121. In an embodiment, the fourth opening OP4 may be formed as a tapered structure that becomes thinner as it moves away from the gate separation structure 135.

Referring to FIG. 8E, by performing an oxidation process through the third opening OP3 and the fourth opening OP4, a portion of the sidewall of each of the first source layer 111, the second source layer 119, and the first semiconductor layer 101 is selectively oxidized. Thus, intervening insulating layers 165A and 165B are formed, respectively, on the sidewall of the first source layer 111 and the sidewall of the second source layer 119 defined along the sidewall of the fourth opening OP4, and an intervening insulating layer 165C is formed on the sidewall of the first semiconductor layer 101 defined along the sidewall of the third opening OP3.

Referring to FIG. 8F, when the first source layer 111, the second source layer 119, and the first semiconductor layer 101 are protected by the intervening insulating layers 165A, 165B, and 165C, the sacrificial stacked body 110S illustrated in FIG. 8E and a portion of the memory layer 123 illustrated in FIG. 8E are removed through the third opening OP3 and the fourth opening OP4. Thus, a fifth opening OP5 is defined between the first source layer 111 and the second source layer 119. During the etching process for forming the fifth opening OP5, each of the intervening insulating layers 165A, 165B, and 165C might not be completely removed and a portion thereof may remain.

The memory layer 123 illustrated in FIG. 8E may be separated into a memory pattern 123A and a dummy pattern 123B by the fifth opening OP5. The channel structure 125 is exposed by the fifth opening OP5.

Referring to FIG. 8G, a contact source layer 171 is formed in the fifth opening OP5 illustrated in FIG. 8F through the third opening OP3 and the fourth opening OP4 illustrated in FIG. 8F. The contact source layer 171 contacts the channel structure 125.

Subsequently, a source contact structure 173 is formed in the third opening OP3 and the fourth opening OP4 illustrated in FIG. 8F. The source contact structure 173 includes a first contact portion 173A in the fourth opening OP4 illustrated in FIG. 8F and a second contact portion 173B in the third opening OP3 illustrated in FIG. 8F. The first contact portion 173A may form a taper portion corresponding to the shape of the fourth opening OP4, and the second contact portion 173B may form a reverse taper portion corresponding to the shape of the third opening OP3.

As described with reference to FIGS. 8F and 8G, after the sacrificial stacked body 110S illustrated in FIG. 8E and a portion of the memory layer 123 illustrated in FIG. 8E are replaced with the contact source layer 171 through the third opening OP3 and the fourth opening OP4, the third opening OP3 and the fourth opening OP4 may be filled with the source contact structure 173. At this time, the contact source layer 171 may be formed of a doped semiconductor layer containing a conductive impurity. The conductive impurity includes an n-type impurity, a p-type impurity, or a mixture thereof. The source contact structure 173 may be formed of various materials. In an embodiment, the source contact structure 173 may be formed of a doped semiconductor layer for the contact source layer 171. In this case, the source contact structure 173 and the contact source layer 171 may be formed of a single doped semiconductor layer. In an embodiment, the source contact structure 173 may include a metal layer or may be formed as a structure in which a doped semiconductor layer and a metal layer are mixed.

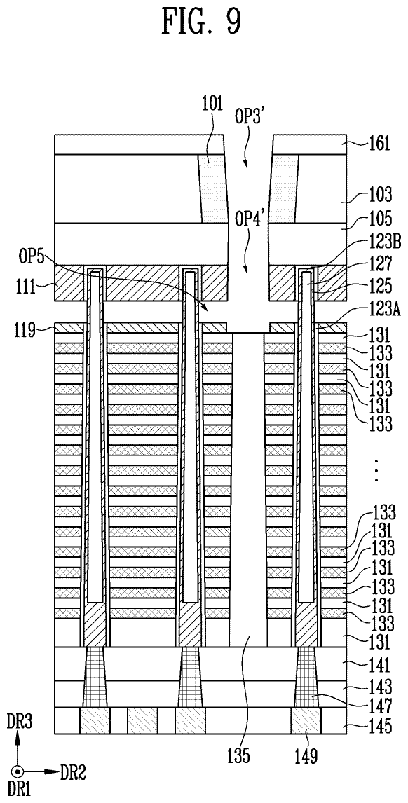

FIG. 9 is a sectional view illustrating a semiconductor memory device provided through a process of removing an intervening insulating layer.

Referring to FIG. 9, after forming the fifth opening OP5 illustrated in FIG. 8F and before forming the contact source layer 171 and the source contact structure 173 illustrated in FIG. 8G, the intervening insulating layers 165A, 165B, and 165C illustrated in FIG. 8F may be removed. Thus, the sidewall of the first semiconductor layer 101, the sidewall of the first source layer 111, and the sidewall of the second source layer 119 are exposed through the third opening OP3′ and the fourth opening OP4′. Thereafter, the process described with reference to FIG. 8G may be performed.

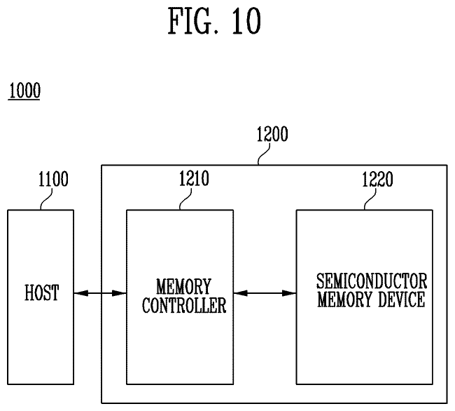

FIG. 10 is a block diagram illustrating an electronic system according to an embodiment of the present disclosure.

Referring to FIG. 10, an electronic system 1000 may be a computing system, a medical device, a communication device, a wearable device, a memory system, etc. The electronic system 1000 may include a host 1100 and a storage device 1200.

The host 1100 may store data in the storage device 1200 or may read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. In an embodiment, the storage device 1200 may be a solid state drive (SSD), a universal serial bus (USB) memory or the like.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include a gate stacked body, a first semiconductor layer over the gate stacked body, a source insulating structure between the first semiconductor layer and the gate stacked body, a contact source layer disposed between the source insulating structure and the gate stacked body, a channel structure penetrating the gate stacked body and contacting the contact source layer, a memory layer between the gate stacked body and the channel structure, and a source contact structure coupled to the contact source layer. The source contact structure may extend to penetrate the source insulating structure and the first semiconductor layer. The source contact structure may include a taper portion and a reverse taper portion, or may be formed as a single layer along with the contact source layer.

According to an embodiment of the present disclosure, it is possible to alleviate warpage stress that may occur during the process of manufacturing a semiconductor memory device by leaving a portion of a semiconductor layer, which is a support substrate. Therefore, an embodiment of the present disclosure may improve the structural stability of the semiconductor memory device.

According to an embodiment of the present disclosure, a contact source layer may be formed through an opening that passes through a semiconductor layer, and a source contact structure may be disposed in the opening to be coupled to the contact source layer. Thus, in an embodiment, even if the height of a gate stacked body increases, the aspect ratio of an opening used as a replacement path of the contact source layer and the aspect ratio of the source contact structure inside the opening do not increase. Therefore, in an embodiment, the structural stability of each of the opening used as the replacement path of the contact source layer and the source contact structure may be improved.

What is claimed is:

1. A semiconductor memory device, comprising:
a gate stacked body including a cell array region and a contact region extending from the cell array region;
a first semiconductor layer disposed over the gate stacked body;
a source insulating structure provided between the first semiconductor layer and the gate stacked body;
a source structure disposed between the source insulating structure and the gate stacked body, and including a contact source layer over the cell array region of the gate stacked body;
a channel structure penetrating the cell array region of the gate stacked body and the source structure, and contacting the contact source layer;
a memory layer disposed between the gate stacked body and the channel structure; and
a source contact structure coupled to the contact source layer, and extending to penetrate the source insulating structure and the first semiconductor layer,
wherein the source contact structure comprises a first contact portion penetrating the source structure and the source insulating structure, and a second contact portion penetrating the first semiconductor layer.

2. The semiconductor memory device according to claim 1, wherein the first contact portion and the second contact portion each comprise a taper portion.

3. The semiconductor memory device according to claim 2, wherein the taper portion of the first contact portion is tapered in an opposite direction to the taper portion of the second contact portion.

4. The semiconductor memory device according to claim 3, wherein the taper portion of the first contact portion becomes thinner in a direction towards the second contact portion.

5. The semiconductor memory device according to claim 3, wherein the taper portion of the second contact portion becomes thinner in a direction towards the first contact portion.

6. The semiconductor memory device according to claim 1, further comprising:
a filling insulating layer overlapping the channel structure, and penetrating the first semiconductor layer.

7. The semiconductor memory device according to claim 1, wherein the gate stacked body comprises a plurality of conductive layers disposed to be spaced apart from each other in a longitudinal direction of the channel structure.

8. The semiconductor memory device according to claim 7, further comprising:
a conductive gate contact plug coupled to a corresponding conductive layer among the plurality of conductive layers in the contact region of the gate stacked body,
wherein at least one conductive layer among the plurality of conductive layers extends to be interposed between the conductive gate contact plug and the source insulating structure.

9. The semiconductor memory device according to claim 7, further comprising:
a conductive gate contact plug penetrating the plurality of conductive layers in the contact region of the gate stacked body, and extending to contact the first semiconductor layer;
an insulating spacer disposed between the conductive gate contact plug and the gate stacked body; and
a pass transistor disposed over the contact region of the gate stacked body, and
wherein the pass transistor comprises a gate electrode disposed between the first semiconductor layer and the source insulating structure, and a first junction and a second junction formed in the first semiconductor layer on both sides of the gate electrode, and
wherein the conductive gate contact plug contacts the second junction and a corresponding conductive layer among the plurality of conductive layers.

10. The semiconductor memory device according to claim 9, wherein the conductive gate contact plug comprises a protruding portion that penetrates the insulating spacer and extends to contact the corresponding conductive layer.

11. The semiconductor memory device according to claim 9, wherein the insulating spacer is separated into an upper spacer and a lower spacer by a contact surface between the corresponding conductive layer and the conductive gate contact plug.

12. The semiconductor memory device according to claim 9, wherein:
the source structure extends between the contact region of the gate stacked body and the source insulating structure, and
the conductive gate contact plug and the insulating spacer extend to penetrate the source structure.

13. The semiconductor memory device according to claim 1, further comprising:
a second semiconductor layer overlapping the first semiconductor layer with the source insulating structure, the source structure, and the gate stacked body interposed between the first semiconductor layer and the second semiconductor layer;
a transistor including first and second junctions within the second semiconductor layer, and a gate electrode disposed over the second semiconductor layer between the first junction and the second junction;
a peripheral circuit insulating structure interposed between the second semiconductor layer and the gate stacked body, and covering the transistor;
an interconnection structure disposed in the peripheral circuit insulating structure and connected to the transistor;
an insulating layer of a multilayer structure disposed between the gate stacked body and the peripheral circuit insulating structure;
a first conductive bonding pattern disposed in the insulating layer of the multilayer structure; and
a second conductive bonding pattern coupling the interconnection structure to the first conductive bonding pattern, and disposed in the peripheral circuit insulating structure.

14. The semiconductor memory device according to claim 1, wherein:
the source structure comprises:
a first source layer disposed between the contact source layer and the source insulating structure, and surrounding the channel structure; and
a second source layer disposed between the contact source layer and the gate stacked body, and surrounding the channel structure, and
each of the contact source layer, the first source layer, and the second source layer comprises a doped semiconductor layer containing an n-type impurity, a p-type impurity, or a mixture of the n-type impurity and the p-type impurity.

15. The semiconductor memory device according to claim 14, further comprising:
an intervening insulating layer disposed between each of the first semiconductor layer, the first source layer, and the second source layer and the source contact structure.

16. The semiconductor memory device according to claim 14, wherein the source contact structure directly contacts each of the first semiconductor layer, the first source layer, and the second source layer.

17. The semiconductor memory device according to claim 14, wherein:
the first source layer and the second source layer extend to overlap the contact region of the gate stacked body,
the source structure comprises a sacrificial stacked body overlapping the contact region of the gate stacked body, and
the sacrificial stacked body comprises at least one layer interposed between the first source layer and the second source layer.

18. A semiconductor memory device, comprising:
a gate stacked body including a cell array region and a contact region extending from the cell array region;
a first semiconductor layer disposed over the gate stacked body;
a source insulating structure provided between the first semiconductor layer and the gate stacked body;
a source structure disposed between the source insulating structure and the gate stacked body, and including a contact source layer over the cell array region of the gate stacked body;
a channel structure penetrating the cell array region of the gate stacked body and the source structure, and contacting the contact source layer;
a memory layer disposed between the gate stacked body and the channel structure; and
a source contact structure coupled to the contact source layer, and extending to penetrate the source insulating structure and the first semiconductor layer,
wherein a single layer includes the contact source layer and the source contact structure.

19. The semiconductor memory device according to claim 18, wherein the single layer comprises a doped semiconductor layer containing an n-type impurity, a p-type impurity, or a mixture of the n-type impurity and the p-type impurity.

20. The semiconductor memory device according to claim 18, further comprising:
a filling insulating layer overlapping the channel structure, and penetrating the first semiconductor layer.

21. The semiconductor memory device according to claim 18, wherein the gate stacked body comprises a plurality of conductive layers disposed to be spaced apart from each other in a longitudinal direction of the channel structure.

22. The semiconductor memory device according to claim 21, further comprising:
a conductive gate contact plug coupled to a corresponding conductive layer among the plurality of conductive layers in the contact region of the gate stacked body,
wherein at least one conductive layer among the plurality of conductive layers extends to be interposed between the conductive gate contact plug and the source insulating structure.

23. The semiconductor memory device according to claim 21, further comprising:
a conductive gate contact plug penetrating the plurality of conductive layers in the contact region of the gate stacked body, and extending to contact the first semiconductor layer;
an insulating spacer provided between the conductive gate contact plug and the gate stacked body; and
a pass transistor disposed over the contact region of the gate stacked body,
wherein the pass transistor comprises a gate electrode provided between the first semiconductor layer and the source insulating structure, and a first junction and a second junction formed in the first semiconductor layer on both sides of the gate electrode, and
wherein the conductive gate contact plug contacts the second junction and a corresponding conductive layer among the plurality of conductive layers.

24. The semiconductor memory device according to claim 23, wherein:
the source structure extends between the contact region of the gate stacked body and the source insulating structure, and
the conductive gate contact plug and the insulating spacer extend to penetrate the source structure.

25. The semiconductor memory device according to claim 18, further comprising:
a second semiconductor layer overlapping the first semiconductor layer with the source insulating structure, the source structure, and the gate stacked body interposed between the first semiconductor layer and the second semiconductor layer;
a transistor including first and second junctions within the second semiconductor layer, and a gate electrode disposed over the second semiconductor layer between the first junction and the second junction;
a peripheral circuit insulating structure interposed between the second semiconductor layer and the gate stacked body, and covering the transistor;
an interconnection structure disposed in the peripheral circuit insulating structure and connected to the transistor;
an insulating layer of a multilayer structure disposed between the gate stacked body and the peripheral circuit insulating structure;
a first conductive bonding pattern disposed in the insulating layer of the multilayer structure; and
a second conductive bonding pattern coupling the interconnection structure to the first conductive bonding pattern, and disposed in the peripheral circuit insulating structure.

26. The semiconductor memory device according to claim 18, wherein the source structure comprises:
a first source layer disposed between the contact source layer and the source insulating structure, and surrounding the channel structure; and
a second source layer disposed between the contact source layer and the gate stacked body, and surrounding the channel structure.

27. The semiconductor memory device according to claim 26, further comprising:
an intervening insulating layer disposed between each of the first semiconductor layer, the first source layer, and the second source layer and the source contact structure.

28. The semiconductor memory device according to claim 26, wherein the source contact structure directly contacts each of the first semiconductor layer, the first source layer, and the second source layer.

29. The semiconductor memory device according to claim 26, wherein:
the first source layer and the second source layer extend to overlap the contact region of the gate stacked body,
the source structure comprises a sacrificial stacked body overlapping the contact region of the gate stacked body, and
the sacrificial stacked body comprises at least one layer interposed between the first source layer and the second source layer.

30. A method of manufacturing a semiconductor memory device, comprising:
forming a source insulating structure over a top surface of a semiconductor layer;
forming a sacrificial stacked body over the source insulating structure;
forming a first vertical structure to penetrate the sacrificial stacked body and the source insulating structure;
forming a cell pillar structure penetrating the sacrificial stacked body at a position spaced apart from the first vertical structure, the cell pillar structure including a channel structure that has a portion protruding in a vertical direction compared to the first vertical structure, and a memory layer extending along a sidewall of the channel structure;
forming a gate stacked body that is disposed over the sacrificial stacked body and surrounds the protruding portion of the cell pillar structure;
removing a portion of the semiconductor layer from a back surface of the semiconductor layer, which faces in a direction opposite to the top surface;
forming an opening that penetrates a remaining portion of the semiconductor layer to expose the first vertical structure;
removing the first vertical structure through the opening; and
replacing a portion of the memory layer and the sacrificial stacked body with a contact source layer through the opening and a region where the first vertical structure is removed.

31. The method according to claim 30, further comprising:
forming a filling insulating layer in the semiconductor layer, and
wherein the cell pillar structure is disposed to overlap the filling insulating layer, and
wherein the first vertical structure is disposed not to overlap the filling insulating layer.

32. The method according to claim 31, wherein removing the portion of the semiconductor layer is stopped when the filling insulating layer is exposed.

33. The method according to claim 30, wherein forming the cell pillar structure comprises:
alternately stacking a plurality of insulating layers and a plurality of sacrificial layer over the sacrificial stacked body one by one;
forming a second vertical structure to penetrate the plurality of insulating layers, the plurality of sacrificial layers, and the sacrificial stacked body;
removing the second vertical structure;
forming the memory layer along a surface of a region where the second vertical structure is removed; and
forming the channel structure in the region where the second vertical structure is removed.

34. The method according to claim 33, further comprising:
forming a third vertical structure penetrating the plurality of sacrificial layers and the plurality of sacrificial layers and coupled to the first vertical structure, while the second vertical structure is formed.

35. The method according to claim 34, wherein forming the gate stacked body comprises:
removing the third vertical structure; and
replacing the plurality of sacrificial layers with a plurality of conductive layers through a region where the third vertical structure is removed.

36. The method according to claim 30, further comprising:
forming a first source layer over the source insulating structure, before forming the sacrificial stacked body; and
forming a second source layer over the sacrificial stacked body, after forming the sacrificial stacked body,
wherein the cell pillar structure and the first vertical structure extend to penetrate the first source layer and the second source layer.

37. The method according to claim 36, further comprising:
forming an insulating layer by oxidizing a sidewall of each of the first source layer, the second source layer, and the first semiconductor layer through the region where the first vertical structure is removed, before replacing the sacrificial stacked body with the contact source layer; and
filling the region where the first vertical structure is removed and the opening with a source contact structure.

38. The method according to claim 37, further comprising:
removing the insulating layer, before forming the contact source layer and the source contact structure.
